(19) United States
(12) Patent Application Publication
(10) Pub. No.: US 2026/0052705 A1
(43) Pub. Date: Feb. 19, 2026

(54) SEMICONDUCTOR DEVICE AND METHOD FOR FABRICATING THE SAME

(71) Applicant: SK hynix Inc., Gyeonggi-do (KR)

(72) Inventors: Jeong Myeong KIM, Gyeonggi-do (KR); Cha Deok DONG, Gyeonggi-do (KR); Eun Kyo BYUN, Gyeonggi-do (KR); Dae Hee LEE, Gyeonggi-do (KR); Bo Kyung JUNG, Gyeonggi-do (KR); Keo Rock CHOI, Gyeonggi-do (KR)

(21) Appl. No.: 19/214,058

(22) Filed: May 21, 2025

(30) Foreign Application Priority Data
Aug. 13, 2024 (KR) 10-2024-0108390

(51) Int. Cl. H10B 63/00; H10N 70/00

(52) U.S. Cl. CPC H10B 63/20; H10B 63/84; H10N 70/023; H10N 70/043; H10N 70/841; H10N 70/8833

(57) ABSTRACT

Disclosed are a semiconductor device, and a method for fabricating the semiconductor device. A semiconductor device comprising: a plurality of memory cells, each of the memory cells including: a memory layer; a first selector layer formed in an upper or lower portion of the memory layer to select the memory layer; a second selector layer to select the memory layer; and an interface layer disposed between the first selector layer and the second selector layer, wherein the first selector layer and the second selector layer include an amorphous silicon layer including one or more dopants selected from a group including group-13 elements, group-14 elements, and group-15 elements of the periodic table, and wherein the interface layer is selected from a group including silicon oxide, silicon carbonitride, silicon carbo-oxynitride, silicon nitride, tantalum nitride, titanium nitride, aluminum nitride, and hafnium nitride.

### CROSS-REFERENCE TO RELATED APPLICATIONS

The present application claims priority under 35 U.S. C 119(a) to Korean Patent Application No. 10-2024-0108390, filed on Aug. 13, 2024, which is incorporated herein by reference in its entirety.

### BACKGROUND

### 1. Field

Embodiments of the present disclosure relate generally to semiconductor technology, and more particularly, to a semiconductor device including a memory cell with a selector, and a method for fabricating the semiconductor device.

### 2. Description of the Related Art

Recently, semiconductor devices capable of storing data in diverse electronic devices, such as computers and portable communication devices, are demanded to cope with the trends of miniaturization, low power consumption, high performance, and diversification of electronic devices. Significant research and development efforts are needed for developing such semiconductor devices. The semiconductor devices capable of storing data by taking advantage of the characteristic of switching between different resistance states according to the applied voltage or current may include a Resistive Random Access Memory (RRAM), a Phase-change Random Access Memory (PRAM), a Ferroelectric Random Access Memory (FRAM), a Magnetic Random Access Memory (MRAM), an e-fuse and the like.

A memory device having a variable resistance element may include a selector as an element for selecting a particular memory cell among a plurality of memory cells that are arrayed, and the selector may be realized as a thin layer in a memory cell.

### SUMMARY

Embodiments of the present disclosure are directed to a semiconductor device with improved selector characteristics of memory cells, and a method for fabricating the semiconductor device.

In accordance with an embodiment of the present disclosure, a semiconductor device includes a plurality of memory cells, wherein each of the memory cells includes a memory layer; a first selector layer formed in an upper or lower portion of the memory layer to select the memory layer; a second selector layer suitable for selecting the memory layer; and an interface layer disposed between the first selector layer and the second selector layer, wherein the first selector layer and the second selector layer include an amorphous silicon layer including one or more dopants selected from a group including group-13 elements, group-14 elements, and group-15 elements of the periodic table, and wherein the interface layer is selected from a group including silicon oxide, silicon carbonitride, silicon carbo-oxynitride, silicon nitride, tantalum nitride, titanium nitride, aluminum nitride, and hafnium nitride.

In accordance with another embodiment of the present disclosure, a method for fabricating a semiconductor device including a first selector layer and a second selector layer in a memory cell to control electrical access to one memory cell among a plurality of memory cells that are arrayed includes forming an amorphous silicon layer including a dopant as the first selector layer over a substrate; depositing an interface layer of a material selected from a group including silicon oxide, silicon carbon nitride, silicon carbo-oxynitride, silicon nitride, tantalum nitride, titanium nitride, aluminum nitride, and hafnium nitride over the first selector layer; forming an amorphous silicon layer including a dopant as the second selector layer over the interface layer; and performing a thermal process at a temperature equal to or lower than a temperature at which the amorphous silicon layer is crystallized.

### BRIEF DESCRIPTION OF THE DRAWINGS

FIGS. 1A and 1B illustrate a semiconductor device in accordance with an embodiment of the present disclosure.

FIGS. 2A and 2B illustrate a semiconductor device in accordance with another embodiment of the present disclosure.

FIG. 3 is a cross-sectional view illustrating a structure of a selector unit in accordance with an embodiment of the present disclosure.

FIGS. 4A to 4H are cross-sectional views illustrating a method for fabricating a semiconductor device in accordance with an embodiment of the present disclosure.

FIGS. 5A to 5H are cross-sectional views illustrating a method for fabricating a semiconductor device in accordance with another embodiment of the present disclosure.

### DETAILED DESCRIPTION

Hereinafter, the various embodiments of the present disclosure will be described in detail with reference to the attached drawings.

Embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

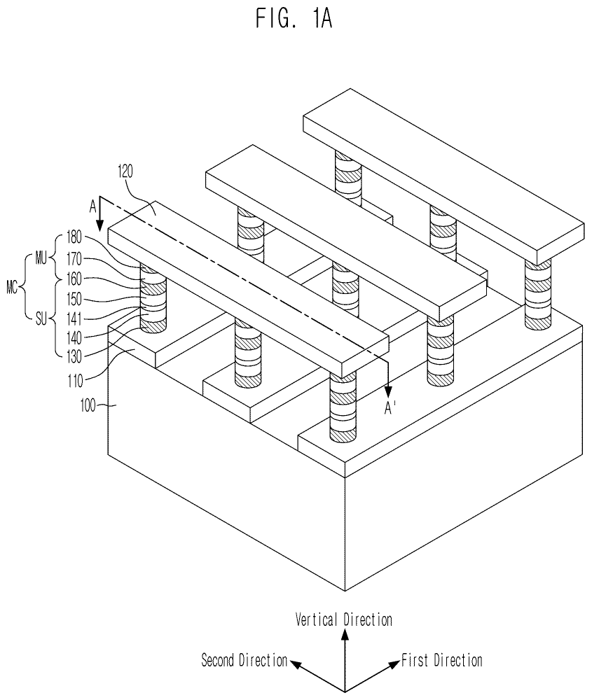

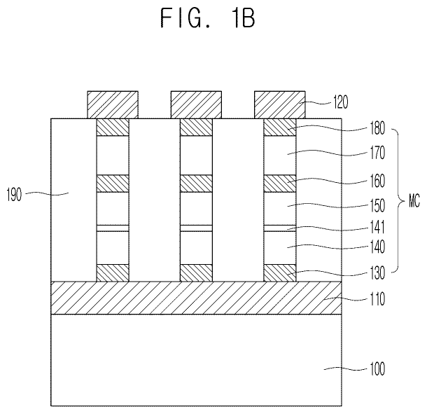

FIGS. 1A and 1B illustrate a semiconductor device in accordance with an embodiment of the present disclosure. FIG. 1A is a perspective view, and FIG. 1B is a cross-sectional view taken along a line A-A′ shown in FIG. 1A. The semiconductor memory in accordance with the embodiment of FIGS. 1A and 1B may have a structure where an interface layer 141 is formed between a first selector layer 140 and a second selector layer 150.

Referring to FIGS. 1A and 1B, the semiconductor device may have a cross-point structure including a substrate 100, a plurality of first conductive lines 110 disposed over the substrate 100 and extending in a first direction, a plurality of second conductive lines 120 disposed over the first conductive lines 110 and extending in a second direction intersecting with the first direction, and a plurality of memory cells MC disposed to overlap with the intersection regions between the first conductive lines 110 and the second conductive lines 120. Here, the first direction and the second direction may mean a direction substantially parallel to the surface of the substrate 100. Hereinafter, a direction substantially perpendicular to the surface of the substrate 100 may be referred to as a vertical direction.

The substrate 100 may include a semiconductor material, such as silicon. Also, a predetermined lower structure (not shown) may be formed in the substrate 100. For example, an integrated circuit for driving the first conductive lines 110 and/or the second conductive line 120 may be formed in the substrate 100.

A plurality of first conductive lines 110 may be disposed spaced apart from each other at a regular interval in the second direction. The first conductive lines 110 may include diverse conductive materials, such as for example, a metal such as platinum (Pt), tungsten (W), aluminum (Al), copper (Cu), tantalum (Ta) and the like, a metal nitride such as titanium nitride (TiN), tantalum nitride (TaN) and the like, or a combination thereof. The first conductive lines 110 may have a single-layer structure or a multi-layer structure.

A plurality of second conductive lines 120 may be disposed spaced apart at a regular interval from each other in the first direction. The second conductive lines 120 may include diverse conductive materials, for example, a metal such as platinum (Pt), tungsten (W), aluminum (Al), copper (Cu), tantalum (Ta) and the like, a metal nitride such as titanium nitride (TiN), tantalum nitride (TaN) and the like, or a combination thereof. The second conductive lines 120 may have a single-layer structure or a multi-layer structure.

Each of the memory cells MC may include a memory unit MU, which is a portion of the memory cell MC where data are actually stored, and a selector unit SU which is a portion of the memory cell MC that controls access to the memory unit MU. Each of the memory cells MC may include a first electrode layer 130 disposed below the first and second selector layers 140 and 150. Each of the memory cells MC may also include second and/or third electrode layers 160 and/or 180 disposed over the first and second selector layers 140 and 150. Moreover, each memory cell may also include an interface layer 141 disposed between the first and second selector layers 140 and 150. The interface layer 141 may include a dielectric material, such as silicon oxide that forms an As—Si—O bond with the first selector layer 140 that is formed through a plasma oxidation process. Also, the interface layer 141 may include an arsenic-silicon oxide, a silicon oxide, silicon carbonitride, silicon carbo-oxynitride, silicon nitride, tantalum nitride, titanium nitride, aluminum nitride, or hafnium nitride, and the interface layer 141 may be formed by chemical oxidation, thermal oxidation, Physical Vapor Deposition (PVD), Chemical Vapor Deposition (CVD), Atomic Layer Deposition (ALD), chemical deposition, a combination of atomic layer deposition (ALD) and chemical vapor deposition (CVD), and/or other appropriate methods. Also, the interface layer 141 may be of a metal oxide, such as aluminum oxide (Al₂O₃), hafnium oxide (HfO₂), titanium oxide (TiO₂), yttrium oxide (Y₂O₃), cerium oxide (CeO₂), scandium oxide (Sc₂O₃), zinc oxide (ZnO), niobium oxide (Nb₂O₅), or tin oxide (SnO₂), however, the technical concept and scope of the present disclosure are not limited thereto. Each of the memory cells MC may include a SiN thin layer at an interface between the first electrode layer 130 and the first selector layer 140, and a carbon (C) thin layer at an interface between the second selector layer 150 and the second electrode layer 160. A SiN thin layer, as used herein, refers to a layer having a thickness of 1 nm to 50 nm, or more specifically, 1 nm to 10 nm. A carbon (C) thin layer, as used herein, refers to a layer having a thickness of 0.5 nm to 20 nm, or more specifically, 0.5 nm to 5 nm.

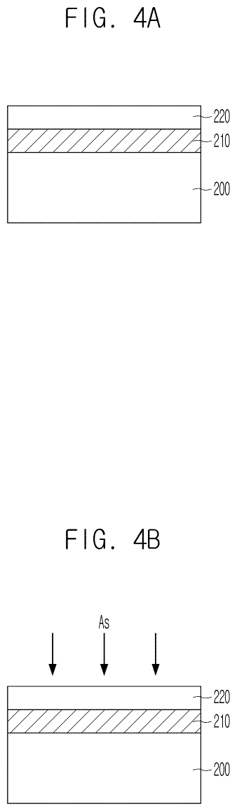

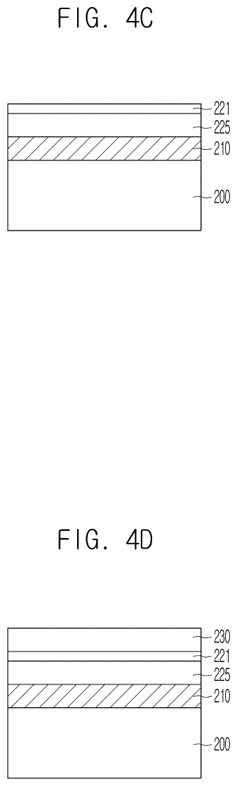

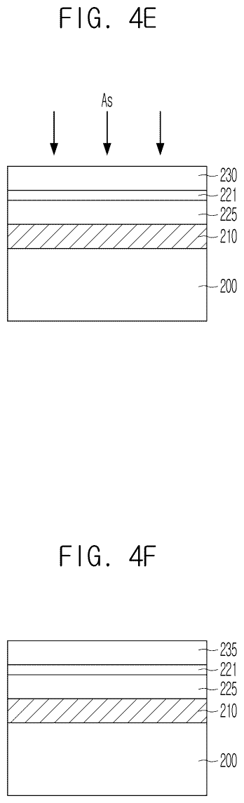

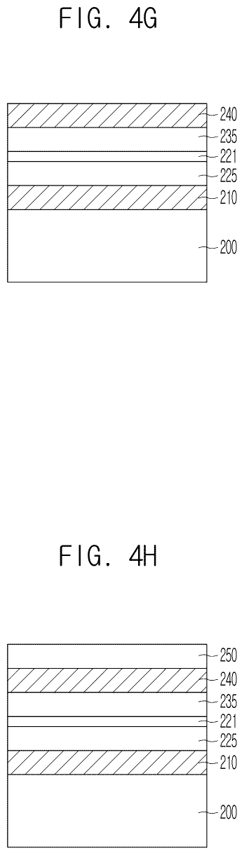

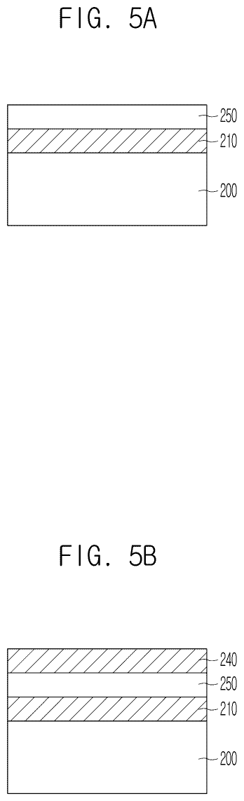

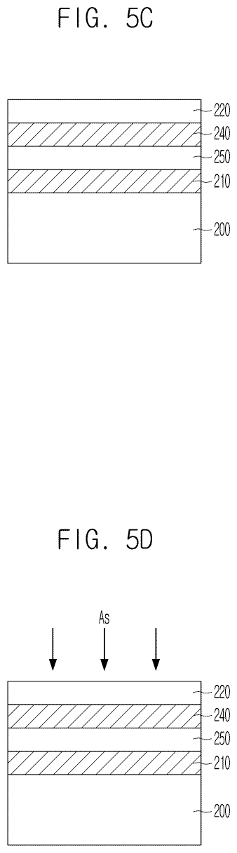

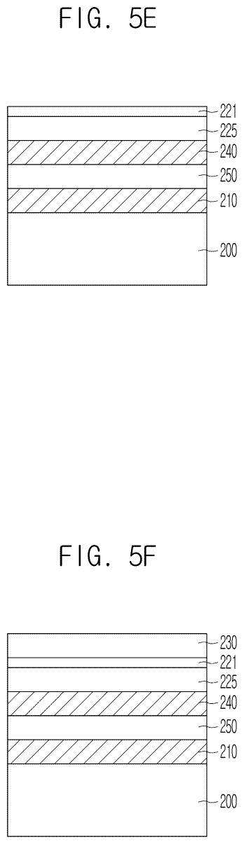

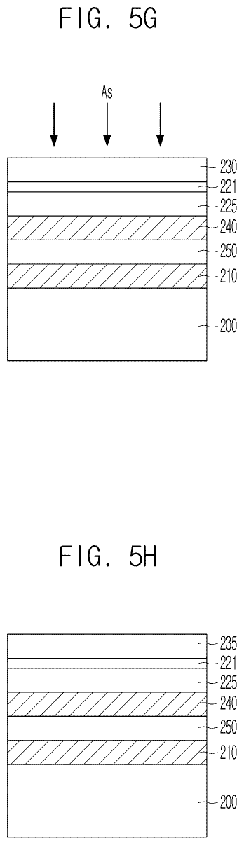

For example, the interface layer 141 may be SiO₂, SiN, SiCN, SiON, or SiCON. The interface layer 141 may be a single layer that forms an As—Si—O bond or a Si—C—O—N bond with the first selector layer 140. The interface layer 141 may be so thin that it does not affect the flow of current. The interface layer 141 may have a thickness that has no electrical significance. The formation of the interface layer 141 will be described in detail later with reference to FIGS. 4A to 5H. The interface layer 141 may be identical to the interface layer 221 illustrated in FIGS. 4C to 4H and FIGS. 5E to 5H, which will be described later.

For example, the memory cell MC may include a stacked structure of the first electrode layer 130, the first selector layer 140, the interface layer 141, the second selector layer 150, the second electrode layer 160, the memory layer 170, and the third electrode layer 180. Here, the selector unit SU may include the first electrode layer 130, the first selector layer 140, the interface layer 141, the second selector layer 150, and the second electrode layer 160, and the memory unit MU may include the second electrode layer 160, the memory layer 170, and the third electrode layer 180. The second electrode layer 160 may be shared by the selector unit SU and the memory unit MU.

The first electrode layer 130 and the third electrode layer 180 may be disposed at both ends of the memory cell MC, that is, at the bottom end and the top end of the memory cell MC, respectively, and may function to apply a voltage or current needed for an operation of the memory cell MC. The second electrode layer 160 may function to electrically connect the first and second selector layers 140 and 150 and the memory layer 170 to each other, while physically separating them from each other. The first electrode layer 130, the second electrode layer 160, or the third electrode layer 180 may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or combinations thereof. Also, the first electrode layer 130, the second electrode layer 160, or the third electrode layer 180 may include a carbon electrode.

The memory layer 170 may function to store data in diverse ways. For example, the memory layer 170 may include a variable resistance layer that stores different data by switching between different resistance states according to the voltage or current supplied through the upper and lower ends of the memory layer 170. The variable resistance layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM) and the like, for example, a metal oxide, such as a transition metal oxide, a perovskite-based material and the like, a phase-change material such as a chalcogenide-based material, a ferroelectric material, a ferromagnetic material, and the like.

The first and second selector layers 140 and 150 may be formed as thin layers in the memory cell. A thin layer, as used herein, refers to a layer having a thickness of 1 nm to 100 nm, 1 nm to 50 nm, or 1 nm to 30 nm. The first and second selector layers 140 and 150 may prevent current leakage between the memory cells MC sharing the first conductive line 110 or the second conductive line 120, while controlling electrical access to one memory cell among the memory cells that are arrayed. To this end, the first and second selector layers 140 and 150 may have threshold switching characteristics of blocking the current or holding the current to hardly flow when the level of the voltage supplied to the upper and lower ends of the first and second selector layers 140 and 150 is lower than a predetermined threshold voltage level, and then letting the current to rapidly flow at a voltage level equal to or higher than the predetermined threshold voltage level. The first and second selector layers 140 and 150 may be turned on at a voltage level equal to or higher than the threshold voltage level and turned off at a voltage level lower than the threshold voltage level.

Typically, the first and second selector layers 140 and 150 may be made of a dielectric material into which a dopant is implanted. Suitable dielectric materials for the first and second selector layers 140 and 150 include, for example, a silicon oxide layer or an amorphous silicon layer. A suitable dopant for the first and second selector layers 140 and 150 includes, for example, an n-type dopant or a p-type dopant. The dopant may be introduced by an ion implantation process. The dopant may include, for example, one or more selected from the group including boron (B), nitrogen (N), carbon (C), phosphorus (P), arsenic (As), aluminum (Al), and germanium (Ge).

The first and second selector layers 140 and 150 may include, for example, an amorphous silicon layer including one or more dopants selected from the group including group-13 elements, group-14 elements, and group-15 elements of the periodic table, and according to a preferred embodiment of the present disclosure, the first and second selector layers 140 and 150 may include, for example, an amorphous silicon layer that is doped with boron (B). This may increase the consistency with an oxide and a nitride of the interface layer 141. According to another embodiment of the present disclosure, the interface layer 141 may be doped with arsenic (As) by additional ion implantation into the amorphous silicon layer that is doped with boron. The formation of the first and second selector layers 140 and 150 will be described in detail later with reference to FIGS. 4A to 5H.

According to embodiments of the present disclosure, the dopant doped into the amorphous silicon layer may be a group-13 element of the periodic table instead of boron (B), and may be a group-14 element or a group-15 element of the periodic table instead of arsenic (As). The potential difference between the first and second selector layers 140 and 150 may be caused by controlling the concentration of the ion-implanted element, for example, arsenic (As). By taking advantage of the potential difference, the formation and threshold voltages may be optimized, and an effective selector operation may be performed. The potential difference between the first and second selector layers 140 and 150 may be formed by changing a formation voltage in terms of a bias application direction, presence or absence of an electrode bonding, and designing of a formation operation, or adjusting the thickness of a base material of the selector layers or the concentration of an element ion-implanted into the first and second selector layers 140 and 150.

According to a combination of the base material of the first and second selector layers 140 and 150 or the ion concentration implanted into the first the second selector layers 140 and 150 and the base material of the interface layer 141, a potential difference may be caused between the first and second selector layers 140 and 150. For example, a P-type selector layer may be a selector layer having a high ion concentration, while the N-type selector layer may be a selector layer having a low ion concentration. Therefore, the first and second selectors 140 and 150 may be used as a P-N-P diode or an N-P-N diode. For example, in the P-N-P diode, the first selector layer 140 may be an N-type selector layer, and the second selector layer 150 may be a P-type selector layer, and in the N-P-N diode, the first selector layer 140 may be a P-type selector layer and the second selector layer 150 may be an N-type selector layer.

Typically, an oxide layer such as SiO₂ may be formed by mixing a source gas containing silicon (Si) and oxygen (O) through a method such as Chemical Vapor Deposition (CVD), Physical Vapor Deposition (PVD), or Atomic Layer Deposition (ALD). Since the deposition-type oxide layer formed in this way has a relatively low density, when a dopant is subsequently introduced by ion implantation, micro voids may be formed inside, or damage may occur to a portion of the surface of the first electrode layer 130 or the second electrode layer 160 disposed in the lower portion of the deposition-type oxide layer, causing a problem of making the interface between the first selector layer 140 and the first electrode layer 130 or the second electrode layer 160 unclear.

The role of the selector in a memory device may be significant. The selector may be used to selectively operate the memory cell, and the selector may require a high on/off ratio and low current leakage. However, a typical selector structure may not be sufficient to satisfy these requirements. Therefore, embodiments of the present disclosure suggest a method for forming a double selector layer using an interface layer to solve this problem.

To solve this problem, according to an embodiment of the present disclosure, the interface layer 141 may be interposed between the first and second selector layers 140 and 150, making it possible to form a double selector layer. This may decrease the current leakage and reduce an off-state current I_{off} and a half-state current I_{half} due to a Schottky barrier operation of the interface layer 141 according to the intensity of the applied bias. Also, a wide potential difference between the first and second selector layers 140 and 150 may be obtained by controlling the base materials of the first selector layer 140, the second selector layer 150, and the interface layer 141 and the concentration of the ion implanted into the first and second selector layers 140 and 150, thereby realizing diverse electrical characteristics of the double selector layer.

Referring back to FIGS. 1A and 1B, the semiconductor device in accordance with the embodiment of the present disclosure may have a structure in which the first selector layer 140, the interface layer 141, and the second selector layer 150 are sequentially stacked over the first electrode layer 130, and then the second electrode layer 160, the memory layer 170, and the third electrode layer 180 are sequentially stacked over the stack of the first electrode layer 130, the first selector layer 140, the interface layer 141, and the second selector layer 150. That is, a structure where the memory layer 170 is formed in the upper portion of the double selector layer may be formed. An inter-layer dielectric material 190 may be implanted between the stacked structures. Generally, silicon oxide (SiO₂), silicon nitride (Si₃N₄), a high-k material and the like may be used for the inter-layer dielectric material 190. The inter-layer dielectric material 190 may be used for inter-layer insulation, may prevent electrical interference, and may provide electrical insulation between elements.

There is no significant difference in the performance of the function of the double selector layer whether the memory layer 170 is disposed in the upper or lower portion of the double selector layer. However, when the memory layer 170 is disposed in the upper portion of the double selector layer, the process may become relatively simple and the bonding between the selector layer and the memory layer may become relatively easier by stacking the memory layer after the formation of the selector layer. However, when the memory layer has to go through a high-temperature process after the formation of the selector layer, the thermal stability of the memory layer may become an issue.

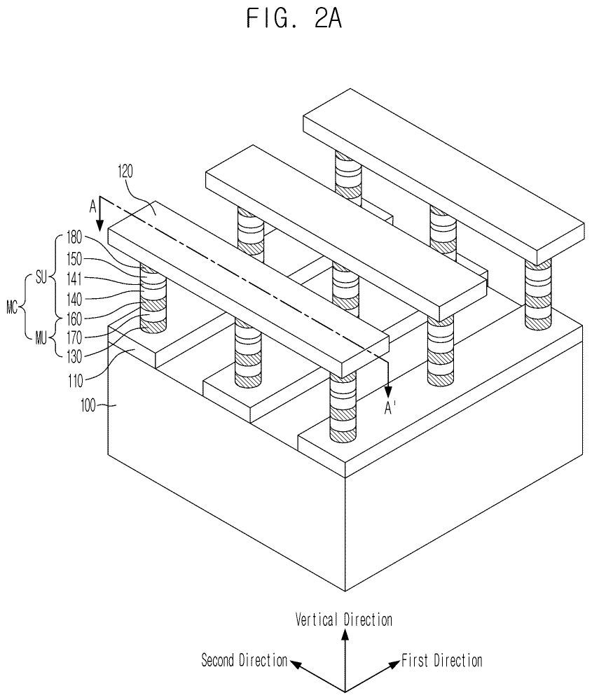

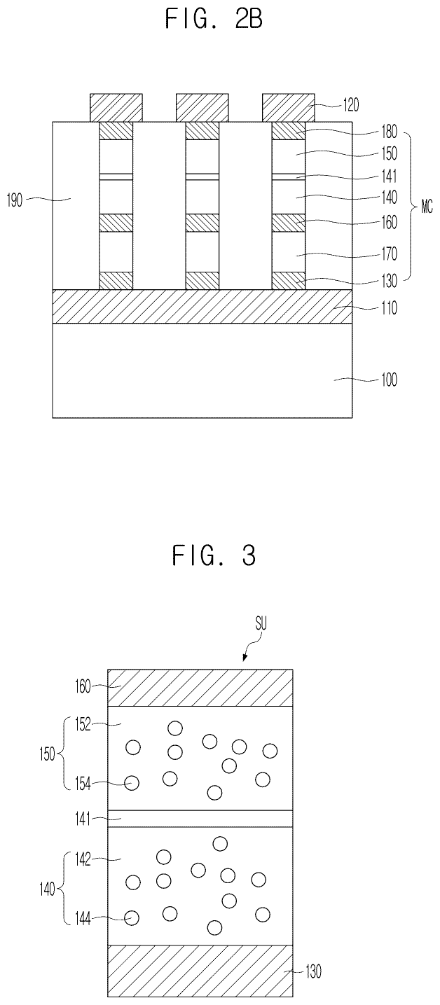

FIGS. 2A and 2B illustrate a semiconductor device in accordance with another embodiment of the present disclosure. FIG. 2A is a perspective view, and FIG. 2B is a cross-sectional view taken along a line A-A′ shown in FIG. 2A. The semiconductor device in accordance with another embodiment of the present disclosure may have a structure in which a memory layer 170 and a second electrode layer 160 are sequentially stacked over a first electrode layer 130, and then a first selector layer 140, an interface layer 141, a second selector layer 150, and a third electrode layer 180 are sequentially stacked over the stacked structure of the first electrode layer 130, the memory layer 170 and the second electrode layer 160. A structure where the memory layer 170 is formed in the lower portion of the double selector layer may be formed. In this case, since the memory layer is disposed in the lower portion, the memory layer may be less affected during a thermal process of the selector layer, and physical damage to the memory layer may be avoided in a subsequent process. However, when the selector layer is formed after the formation of the memory layer, the process may become relatively complicated, and inter-layer bonding between the memory layer and the selector layer may become relatively difficult.

The semiconductor device illustrated in FIGS. 2A and 2B may be similar to the semiconductor device shown in FIGS. 1A and 1B except that the double selector layer including the first selector layer 140, the interface layer 141, and the second selector layer 150 is formed in the upper portion of the memory layer 170. As for what is similar to the embodiment of the present disclosure illustrated in FIGS. 1A and 1B, a detailed description of it will be omitted herein. Even with this embodiment of the present disclosure, all advantages described in the above-described embodiment of the present disclosure may be obtained.

Although FIGS. 1A to 2B show the memory cell MC having a stacked structure of the first electrode layer 130, the first selector layer 140, the interface layer 141, the second selector layer 150, the second electrode layer 160, the memory layer 170, and the third electrode layer 180, the technical concepts and scope of the present disclosure are not limited thereto, and the layer structure of the memory cell MC may be diversely modified. For example, at least one of the first electrode layer 130, the second electrode layer 160, and the third electrode layer 180 may be omitted. For example, the memory cell MC may include the first and second selector layers 140 and 150, the first electrode layer 130 or the second electrode layer 160 disposed below the first selector layer 140, and the second electrode layer 160 or the third electrode layer 180 disposed over the second selector layer 150. For example, the first electrode layer 130 disposed below the first selector layer 140 may include titanium nitride (TiN), and the third electrode layer 180 disposed over the second selector layer 150 may include a carbon (C) electrode. Also, for example, the upper and lower positions of the double selector layer and the memory layer 170 may be switched with each other. Also, for example, the memory cell MC may further include one or more layers (not shown) to enhance the characteristics or improve the process.

FIG. 3 is a cross-sectional view illustrating a structure of a selector unit in accordance with an embodiment of the present disclosure.

Referring to FIG. 3, the selector unit SU may include a first electrode layer 130, a first selector layer 140, an interface layer 141, a second electrode layer 150, and a second electrode layer 160.

As described above, the first and second electrode layers 130 and 160 may include diverse conductive materials, such as metals, metal nitrides, and the like. The first and second electrode layers 130 and 160 may be formed of the same material so as to have the same work function. For example, the first and second electrode layers 130 and 160 may include titanium nitride (TiN) having a work function of approximately 4.4 to 4.6 eV. However, the technical concepts and scope of the present disclosure are not limited thereto, and the first and second electrode layers 130 and 160 may be formed of different materials so as to have different work functions. As used herein, the term ‘approximately’ when referring to a numerical range means within ±5% of the stated value.

The first and second selector layers 140 and 150 may include, for example, an amorphous silicon layer 142 and dopants 144 and 154 implanted into the amorphous silicon layer 142.

The amorphous silicon layer 142 may be a dielectric material having a relatively wide band gap, to be specific, a dielectric material having a band gap of approximately 5.0 eV or more. For example, a deep trap whose energy level is closer to the energy level of a valence band than to the energy level of a conduction band of a thin layer may exist in the amorphous silicon layer 142. The dopant 144 may serve to create a shallow trap that provides a path for conductive carriers, such as electrons or holes, to move in the amorphous silicon layer 142. The shallow trap may have an energy level which is closer to the energy level of the conduction band than to the energy level of the valence band of the amorphous silicon layer 142.

The dopant 144 may include one or more selected from the group including group-13 elements, group-14 elements, and group-15 elements of the periodic table whose atomic valences are different from the atomic valence of silicon (Si). For example, the dopant 144 may include a group-13 element of the periodic table, such as boron (B), aluminum (Al), gallium (Ga), or indium (In). For example, the dopant 144 may include a group-14 element of the periodic table, such as carbon (C), silicon (Si), germanium (Ge), or tin (Sn), together with a group-13 element of the periodic table. For example, the dopant 144 may include a group-15 element of the periodic table, such as nitrogen (N), phosphorus (P), arsenic (As), or antimony (Sb), together with a group-13 element of the periodic table. For example, the dopant 144 may include boron (B), and may further include one or more of phosphorus (P) and arsenic (As) together with boron (B).

The dopant concentration and the ratio of amorphous silicon in the doped amorphous silicon layer may vary significantly according to the process conditions. The dopant concentration may be adjusted by controlling the flow rate and hydraulic pressure of diborane (B₂H₆) and silane gas (SiₓH_{y}). For example, increasing the flow rate of diborane (B₂H₆) may increase the dopant concentration, and conversely, increasing the flow rate of silane gas (SiₓH_{y}) may increase the ratio of amorphous silicon. When a doped amorphous silicon layer is generated by reacting diborane and silane gas with each other under the temperature condition of approximately 300° C., the dopant 144 in the doped amorphous silicon layer may have a concentration of approximately 10 to 30 wt%, and the amorphous silicon may have a concentration of approximately 90 to 70 wt%. When the doped amorphous silicon layer is generated by reacting diborane and silane gas under the temperature condition of approximately 400° C., the diffusion of the dopant may become more active, and the dopant may be more easily doped into the amorphous silicon layer. Therefore, in this case, the dopant 144 in the doped amorphous silicon layer may have a concentration of approximately 30 to 90 wt%, and the amorphous silicon may have a concentration of approximately 70 to 10 wt%.

FIGS. 4A to 4H are cross-sectional views illustrating a method for fabricating a semiconductor device in accordance with an embodiment of the present disclosure.

Referring to FIG. 4A, a substrate 200 having a predetermined lower structure formed thereon may be provided. The substrate 200 may include diverse circuits. For example, the substrate 200 may include a conductive line which is similar to the first conductive line 110 of FIGS. 1A and 2A described above.

Subsequently, a first electrode layer 210 may be formed over the substrate 200. The first electrode layer 210 may be formed as a TiN thin layer. A TiN thin layer, as used herein, refers to a layer having a thickness of 5 nm to 100 nm, or more specifically, 5 nm to 50 nm.

Subsequently, an initial first selector layer 220 may be formed over the first electrode layer 210. The initial first selector layer 220 may include a silicon oxide layer or an amorphous silicon layer that is doped with a first dopant as a silicon (Si)-containing layer. Here, the method for forming the silicon oxide layer or the amorphous silicon layer that is doped with the first dopant may be realized as a method of depositing a silicon oxide layer or an amorphous silicon layer that is doped with the first dopant. The first dopant may include at least one selected from the group including boron (B), nitrogen (N), carbon (C), phosphorus (P), arsenic (As), aluminum (Al), and germanium (Ge).

The amorphous silicon layer including the first dopant may be formed by a Low-Pressure Chemical Vapor Deposition (LPCVD) process using a first dopant-containing catalyst and a silicon source gas. For example, the amorphous silicon layer including the first dopant may be formed by a Low-Pressure Chemical Vapor Deposition (LPCVD) process using silane gas (SiₓH_{y}), e.g., SiH₄,and diborane (B₂H₆). The Low-Pressure Chemical Vapor Deposition (LPCVD) process may provide a uniform thin layer and a low defect rate, thereby improving the performance of a semiconductor device.

When boron (B) is applied as the first dopant, a boron-containing catalyst may be selected from the group including trimethyl borate (B(Ome)₃), boron trichloride (BCI₃), boron tribromide (BBr₃), boron dibromide (BBr₂), boron trifluoride (BF₃), or diborane (B₂H₆). In the case of the boron (B)-containing catalyst that does not contain hydrogen in itself, it may be supplied together with hydrogen (H₂).

Subsequently, referring to FIG. 4B, a second dopant, for example, arsenic (As), may be ion-implanted into the amorphous silicon layer including the first dopant. In addition to arsenic (As), the second dopant may include a group-14 element of the periodic table, for example, carbon (C), silicon (Si), germanium (Ge), or tin (Sn), or a group-15 element of the periodic table, for example, nitrogen (N), phosphorus (P), or antimony (Sb). According to an embodiment of the present disclosure, the first dopant may include boron (B), and the second dopant may include one or more selected from the group including carbon (C), silicon (Si), germanium (Ge), phosphorus (P), and arsenic (As). The ion implantation of the second dopant may be performed in a direction substantially perpendicular to the surface of the substrate 200. However, an angled ion implantation may also be performed. The ion implantation process may be performed repeatedly several times. Electrical characteristics may be given to a semiconductor device that is fabricated by ion-implanting the second dopant, such as arsenic (As), into the amorphous silicon layer. The characteristics of the semiconductor device may be appropriately changed by changing the concentration of the ion-implanted second dopant. For example, the concentration may be adjusted in the range of approximately 10% to 50% according to the implantation conditions.

An amorphous silicon layer into which the second dopant is additionally ion-implanted may be easily secured, and a conductive path in the amorphous silicon layer may be easily secured due to a second dopant impact during the ion-implantation process.

This ion implantation process may be performed with high energy and a high ion implantation amount, and since the ions such as arsenic (As) are heavy components having a large mass, the ion implantation process may be performed under the condition that the layer material hardly endures. According to the embodiment of the present disclosure, the second dopant may be absorbed into the vacancy between silicon (Si) and hydrogen (H) in the amorphous silicon layer including the first dopant. Therefore, the layer material may be able to endure such harsh conditions during the ion implantation process. This may prevent defects such as micro voids from being formed inside.

Subsequently, referring to FIG. 4C, a first selector layer 225 in which the second dopant is ion-implanted into the amorphous silicon layer including the first dopant may be formed out of the initial first selector layer 220 due to the ion implantation process illustrated in FIG. 4B, and an interface layer 221 may be deposited over the first selector layer 225. The interface layer 221 may be formed by being deposited through chemical oxidation, thermal oxidation, Physical Vapor Deposition (PVD), Chemical Vapor Deposition (CVD), Atomic Layer Deposition (ALD), chemical deposition, a combination of atomic layer deposition (ALD) and chemical vapor deposition (CVD), and/or other appropriate methods. The base material and deposition method of the interface layer 221 may be appropriately selected in consideration of the electrical characteristics of the double selector layer.

Subsequently, referring to FIG. 4D, an initial second selector layer 230 may be formed over the interface layer 221. The base material of the initial second selector layer 230 may be the same as the base material of the initial first selector layer 220, and thus may include a silicon oxide layer or an amorphous silicon layer that is doped with the first dopant as a silicon (Si)-containing layer. Referring to FIG. 4E, a second dopant, for example, arsenic (As), may be ion-implanted into the amorphous silicon layer including the first dopant, as illustrated in FIG. 4B. Referring to FIG. 4F, through the ion implantation process of FIG. 4E, a second selector layer 235 in which the second dopant is ion-implanted into the amorphous silicon layer including the first dopant may be formed out of the initial second selector layer 230.

Referring to FIG. 4G, a second electrode layer 240 may be formed over the second selector layer 235. The second electrode layer 240 may be formed by a method of depositing a conductive material. The second electrode layer 240 may be formed as a single TiN thin layer, or the second electrode layer 240 may be formed by stacking a carbon (C) thin layer and a TiN layer. In this case, the carbon (C) thin layer may be formed at the interface between the amorphous silicon layer and the TiN layer.

Referring to FIG. 4H, a memory layer 250 may be deposited over the second electrode layer 240 so as to fabricate a semiconductor device in which the memory layer 250 is formed over the double selector layer. The amorphous silicon layer including the first and/or second dopant as the first selector layer 225 and the second selector layer 235 in accordance with one embodiment of the present disclosure may have to exist in an amorphous state in the final fabrication result of the semiconductor device. Typically, a high temperature process of approximately 400° C. or higher may not be followed in the fabrication of a variable resistance memory element. Therefore, in the semiconductor device of the final result fabricated according to one embodiment of the present disclosure, the amorphous silicon layer as a double selector may exist in an amorphous state that is not crystallized. The semiconductor device in accordance with the embodiment of the present disclosure may be fabricated through the process described above.

Referring back to FIG. 4H, the semiconductor device in accordance with the embodiment of the present disclosure may have a structure including the substrate 200, the first electrode layer 210 over the substrate 200, the first selector layer 225, the interface layer 221, and the second selector layer 235 that are sequentially stacked over the first electrode layer 210 so as to produce a stack of the substrate 200, the first electrode layer 210, and the first selector layer 225, the interface layer 221, and the second selector layer 235. The structure may further include the second electrode layer 240 and the memory layer 250 that are sequentially stacked over the stack of the substrate 200, the first electrode layer 210, the first selector layer 225, the interface layer 221, and the second selector layer 235.

FIGS. 5A to 5H are cross-sectional views illustrating a method for fabricating a semiconductor device with the memory layer 250 formed in the lower portion of the double selector layer in accordance with another embodiment of the present disclosure. The method for fabricating the semiconductor device shown in FIGS. 5A to 5H may be similar to the method for fabricating the semiconductor device shown in FIGS. 4A to 4H, except that the memory layer 250 is formed in the lower portion of the double selector layer. As for what is similar to the embodiment of the present disclosure illustrated in FIGS. 4A to 4H, a detailed description of it will be omitted herein.

Referring to FIG. 5A, a substrate 200 having a predetermined lower structure formed therein may be provided, and a first electrode layer 210 and a memory layer 250 may be sequentially formed over the substrate 200.

Subsequently, referring to FIGS. 5B to 5D, a second electrode layer 240 and an initial first selector layer 220 may be formed over the memory layer 250, and a second dopant, for example, arsenic (As), may be ion-implanted into an amorphous silicon layer including a first dopant.

Subsequently, referring to FIGS. 5E and 5F, a first selector layer 225 in which the second dopant is ion-implanted into the amorphous silicon layer including the first dopant may be formed out of the initial first selector layer 220 by the ion implantation process of FIG. 5D. Subsequently, an interface layer 221 may be deposited and an initial second selector layer 230 may be formed in the same manner as illustrated in FIGS. 4C to 4F.

Referring to FIG. 5G, a second selector layer 235 in which a second dopant is ion-implanted into the amorphous silicon layer including the first dopant may be formed out of the initial second selector layer 230 through the ion implantation process.

Subsequently, referring to FIG. 5H, a semiconductor device in which the memory layer 250 is formed in the lower portion of a double selector layer may be fabricated. The semiconductor device in accordance with the embodiment of the present disclosure may be fabricated through the process described above.

Referring back to FIG. 5H, the semiconductor device in accordance with the embodiment of the present disclosure may have a structure including the substrate 200, the first electrode layer 210 over the substrate 200, the memory layer 250 and the second electrode layer that are sequentially stacked over the first electrode layer 210 so as to produce a stack of the substrate 200, the first electrode layer 210, the memory layer 250 and the second electrode layer. The first selector layer 225, the interface layer 221, and the second selector layer 235 are also sequentially stacked over the stack of the substrate 200, the first electrode layer 210, the memory layer 250 and the second electrode layer.

According to Embodiments of the Present Disclosure, the semiconductor device and a fabrication method thereof may have improved selector characteristics by forming a double selector layer in a memory cell.

While the embodiments of the present disclosure have been described with respect to specific embodiments, it will be apparent to those skilled in the art that various changes and modifications may be made without departing from the technical concepts and scope of the present disclosure as defined in the following claims. Furthermore, the embodiments may be combined to form additional embodiments.

What is claimed is:

1. A semiconductor device comprising:
a plurality of memory cells, each of the memory cells including:
a memory layer;
a first selector layer formed in an upper or a lower portion of the memory layer to select the memory layer;
a second selector layer to select the memory layer; and
an interface layer disposed between the first selector layer and the second selector layer,
wherein the first selector layer and the second selector layer include an amorphous silicon layer including one or more dopants selected from a group including group-13 elements, group-14 elements, and group-15 elements of the periodic table, and
wherein the interface layer is selected from a group including silicon oxide, silicon carbonitride, silicon carbo-oxynitride, silicon nitride, tantalum nitride, titanium nitride, aluminum nitride, and hafnium nitride.

2. The semiconductor device of claim 1, wherein the dopant includes a group-13 element of the periodic table.

3. The semiconductor device of claim 1, wherein the dopant includes a group-13 element and a group-14 element of the periodic table.

4. The semiconductor device of claim 1, wherein the dopant includes a group-13 element and a group-15 element of the periodic table.

5. The semiconductor device of claim 1, wherein the dopant includes boron (B).

6. The semiconductor device of claim 1, wherein the dopant includes at least one of phosphorus (P) and arsenic (As), and boron (B).

7. The semiconductor device of claim 1, wherein the dopant includes at least one selected from a group including carbon (C), silicon (Si) and germanium (Ge), and boron (B).

8. The semiconductor device of claim 1, wherein the dopant has a concentration of approximately 10 to 30 wt% in the doped amorphous silicon layer.

9. The semiconductor device of claim 1, wherein the memory cell further includes
a first electrode layer disposed below the first selector layer or the second selector layer, and
a second electrode layer disposed over the first selector layer or the second selector layer.

10. The semiconductor device of claim 9, wherein the first electrode layer and the second electrode layer include a TiN thin layer.

11. The semiconductor device of claim 9, further comprising:
a SiN thin layer at an interface between the first electrode layer and the first selector layer or the second selector layer, and
a carbon (C) thin layer at an interface between the first selector layer or the second selector layer and the second electrode layer.

12. A method for fabricating a semiconductor device including a first selector layer and a second selector layer in a memory cell to control electrical access to one memory cell among a plurality of memory cells that are arrayed, the method comprising:
forming an amorphous silicon layer including a dopant as the first selector layer over a substrate;
depositing an interface layer of a material selected from a group including silicon oxide, silicon carbon nitride, silicon carbo-oxynitride, silicon nitride, tantalum nitride, titanium nitride, aluminum nitride, and hafnium nitride over the first selector layer;
forming an amorphous silicon layer including a dopant as the second selector layer over the interface layer; and
performing a thermal process at a temperature equal to or lower than a temperature at which the amorphous silicon layer is crystallized.

13. The method of claim 12, wherein forming the amorphous silicon layer includes
depositing an amorphous silicon layer that is doped with a first dopant.

14. The method of claim 13, wherein the first dopant has a concentration of approximately 10 to 30 wt% in the doped amorphous silicon layer.

15. The method of claim 12, further comprising:
forming an electrode layer over the second selector layer.

16. The method of claim 12, wherein forming the amorphous silicon layer includes:
depositing an amorphous silicon layer that is doped with a first dopant; and
ion-implanting a second dopant into the amorphous silicon layer that is doped with the first dopant.

17. The method of claim 16, wherein the first dopant includes a group-13 element of the periodic table, and
the second dopant includes a group-14 element or a group-15 element of the periodic table.

18. The method of claim 16, wherein the first dopant includes boron (B), and
the second dopant includes at least one selected from a group including carbon (C), silicon (Si), germanium (Ge), phosphorus (P), and arsenic (As).

19. The method of claim 12, wherein the thermal process is performed at a temperature of approximately 400°C or lower.

20. The method of claim 13, wherein depositing the amorphous silicon layer including the first dopant is performed by a Low-Pressure Chemical Vapor Deposition (LPCVD) process using SiH₄ and diborane (B₂H₆).
